(19) United States
(12) Patent Application Publication
(10) Pub. No.: US 2019/0311884 A1
(43) Pub. Date: Oct. 10, 2019

(54) RF TAILORED VOLTAGE ON BIAS OPERATION

(71) Applicant: Applied Materials, Inc., Santa Clara, CA (US)

(72) Inventors: Satoru KOBAYASHI, Sunnyvale, CA (US); Wei TIAN, Sunnyvale, CA (US); Shahid RAUF, Pleasanton, CA (US); Junghoon KIM, Santa Clara, CA (US); Soonam PARK, Sunnyvale, CA (US); Dmitry LUBOMIRSKY, Cupertino, CA (US)

(21) Appl. No.: 16/374,835

(22) Filed: Apr. 4, 2019

Related U.S. Application Data
(60) Provisional application No. 62/669,233, filed on May 9, 2018.
(60) Provisional application No. 62/652,802, filed on Apr. 4, 2018.

(30) Foreign Application Priority Data
Mar. 22, 2019 (TW) 108109975

(51) Int. Cl. H01J 37/32; C23C 16/455; C23C 16/52

(52) U.S. Cl. CPC H01J 37/32146; H01J 37/32165; H01J 37/32183; H01J 2237/3321; C23C 16/45565; C23C 16/52; H01J 2237/3341; H01J 37/32568

(57) ABSTRACT

A method, system, and apparatus for reducing particle generation on a showerhead during an ion bombarding process in a process chamber are provided. First and second RF signals are supplied from an RF generator to an electrode embedded in a substrate support in the process chamber. The second RF signal is adjusted relative to the first RF signal in response to a measurement of a first RF amplitude, a second RF amplitude, a first RF phase, and a second RF phase. Ion bombardment on a substrate is maximized and the quantity of particles generated on the showerhead is minimized. Methods and systems described herein provide for improved ion etching characteristics while reducing the amount of debris particles generated from the showerhead.

### CROSS-REFERENCE TO RELATED APPLICATIONS

This application claims benefit of U.S. Provisional Patent Application No. 62/652,802, filed Apr. 4, 2018, U.S. Provisional Patent Application No. 62/669,233, filed May 9, 2018, and Taiwan Patent Application number 108109975, filed on Mar. 22, 2019, each of which is herein incorporated by reference.

### BACKGROUND

### Field

Embodiments of the present disclosure generally relate to methods and systems of controlling plasma in a process chamber.

### Description of the Related Art

Processing chambers are conventionally used to perform plasma processing of substrates, such as etch or deposition processes. During etch or deposition processes, particles may be deposited on a showerhead within the processing chamber. The material deposited on the showerhead can fall on to the substrate or substrate support below and contaminate the substrate and processing volume within the chamber.

Therefore, there is a need for controlling and reducing particle generation in a processing chamber.

### SUMMARY

The present disclosure generally describes a method, system, and apparatus for reducing particle generation from a showerhead. In one example, a substrate processing method is provided. The method includes supplying a first RF (radio frequency) signal having a first frequency, a first amplitude, and a first phase. The first RF signal is supplied from an RF generator to an electrode embedded in a substrate support disposed in a process chamber. A second RF signal having a second frequency, a second amplitude, and a second phase is supplied from the RF generator to the electrode. The method further includes adjusting the second RF signal relative to the first RF signal to generate ions. The adjusting the second RF signal is performed in response to a measurement of the first amplitude, the first phase, the second amplitude, and the second phase.

In another example, a system for processing a substrate is disclosed. The system includes a process chamber having a substrate support disposed in a processing volume of a process chamber. A showerhead is disposed above the substrate support in the processing volume of the process chamber. An electrode is embedded in a substrate support surface of the substrate support. An RF generator is coupled to the first electrode to supply a first RF signal having a first frequency, a first amplitude, and a first phase and a second RF signal having a second frequency, second amplitude, and a second phase to the first electrode. A controller is connected to the RF generator to adjust the second RF signal relative to the first RF signals in response to a measurement of the first and second amplitudes and phases to generate ions for etching a substrate.

In another example, an apparatus for processing a substrate is disclosed. The apparatus includes a process chamber having a substrate support disposed in a processing volume of a process chamber. A showerhead is disposed above the substrate support in the processing volume of the process chamber. An electrode is embedded in a substrate support surface of the substrate support. An RF generator is coupled to the first electrode to supply a first RF signal having a first frequency, first amplitude, and a first phase and a second RF signal having a second frequency, a second amplitude, and a second phase to the first electrode. A controller is connected to the RF generator to adjust the second RF signal relative to the first RF signal in response to a measurement of the first and second amplitudes and phases to generate ions which are maximized adjacent to the substrate support surface and minimized adjacent to the showerhead.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1 depicts a schematic view of a processing system according to one embodiment of the disclosure.

FIG. 2 illustrates calculated RF voltage forms according to one embodiment of the disclosure.

FIG. 3 illustrates calculated RF voltage forms according to one embodiment the disclosure.

FIG. 4A illustrates a calculated DC self-bias voltage form according to one embodiment of the disclosure.

FIG. 4B illustrates a calculated bulk plasma potential voltage form according to one embodiment of the disclosure.

FIG. 5 depicts a schematic view of a processing system according to one embodiment of the disclosure.

FIG. 6 depicts a flow chart of an algorithm to identify an RF tailored voltage by attaining target RF voltage parameters according to one embodiment of the disclosure.

FIG. 7 depicts a block diagram of a frequency generator according to one embodiment of the disclosure.

FIG. 8 depicts a block diagram of an amplitude and phase generator according to one embodiment of the disclosure.

FIG. 9 depicts a block diagram of an RF voltage monitor according to one embodiment of the disclosure.

FIG. 10 depicts a block diagram of an IQ detector according to one embodiment of the disclosure.

FIG. 11 depicts a method of controlling ion bombardment in a process chamber according to one embodiment of the disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to plasma processing of substrates, such as etching and deposition of substrates. During etch and deposition processes, a capacitively-coupled plasma is generated between two electrodes, for example, a first electrode disposed within a substrate support and a second electrode in a showerhead. The substrate support electrode is connected to an RF generator and the showerhead electrode is connected to an electric ground or RF return. The plasma generated within the process chamber facilitates etching of material from, or deposition of material onto, a substrate.

Aspects of the present disclosure relate to controlling the phase and voltage of the RF signal to simultaneously control deposition or etching with respect to the substrate, while reducing particle generation (e.g., flaking) from the showerhead or other upper electrode. Moreover, aspects herein relate to identification of phase differences between frequencies to facilitate an increase in deposition or etching with respect to the substrate, while reducing the particle generation (e.g., flaking) from the showerhead or other upper electrode.

Methods and systems for reducing particle generation from a showerhead during an ion bombarding process in a process chamber are provided. A first RF signal and a second RF signal are supplied from an RF generator to a first electrode embedded in a substrate support disposed in a process chamber. The second RF signal is adjusted relative to the first RF signal in response to measured characteristics of the first and second RF signals, for example, a first amplitude and a first phase of the first RF signal and a second amplitude and a second phase of the second RF signal. In some embodiments, which can be combined with one or more embodiments described above, ion bombardment on a substrate is increased and the quantity of particles generated from the showerhead is reduced. Methods and systems herein enable etching through the utilization of ion bombardment, while reducing the amount of debris particles generated from the showerhead. In addition, a method of increasing accuracy of the RF voltage/current monitor by combining information from an RF match is discussed.

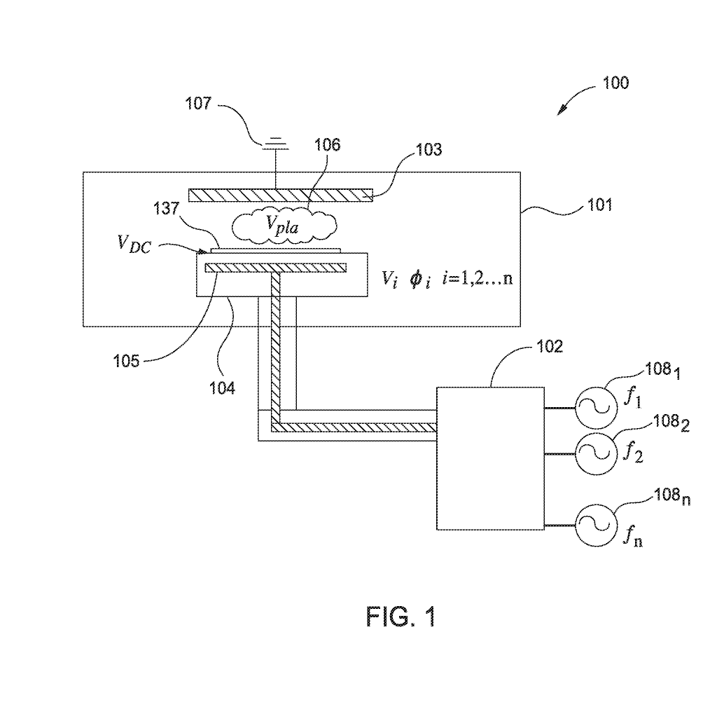

FIG. 1 depicts a schematic view of a processing system 100 for performing a multi-frequency bias operation in a process chamber 101. The processing system 100 includes the process chamber 101 connected to multiple RF generators 108 through an n-frequency RF match 102. The process chamber 101 includes a showerhead 103 disposed therein and connected to an electric ground 107 (or an RF return). A substrate support 104 is disposed in the process chamber 101 opposite the showerhead 103. A substrate 137 is supported by the substrate support 104. Embedded within substrate support 104 is an electrode 105. The electrode 105 is connected to the n-frequency RF match 102. The n-frequency RF match 102 applies power to the electrode 105 at a respective voltage (Vᵢ) and phase (ϕᵢ) for each respective frequency (fᵢ). The electrode 105 and the showerhead 103 facilitate generation of a capacitively-coupled plasma 106.

According to one embodiment, which can be combined with one or more embodiments described above, a multi-frequency bias operation is performed in the process chamber 101. During processing, the electrode 105 is biased by multiple frequencies (for example, two different frequencies), via the n-frequency RF match 102, while the showerhead 103 (e.g., second electrode) is connected to the electric ground 107 to facilitate RF return. In one example, frequencies applied by the n-frequency RF match 102 may be integer multiples of one another, for example, RF energy may be applied at both a first frequency of 13.56 MHz and a second frequency of 27.12 MHz. In some embodiments, which can be combined with one or more embodiments described above, the first frequency and the second frequency are harmonic frequencies. In some embodiments, which can be combined with one or more embodiments described above, the first frequency and the second frequency are adjacent harmonic frequencies.

Additionally, a surface area of the showerhead 103 is larger than a surface area of the substrate support 104.

When operating the process chamber 101 with multi-harmonic frequencies, the plasma 106, with a time averaged bulk plasma potential of Vₚₗₐ, is generated with a time averaged self-bias DC voltage of V_{DC} formed on the substrate support 104. When using dual-frequency plasma generation, it is believed that at a certain phase value (ϕ), ion bombardment on the substrate 137, defined by |Vₚₗₐ−V_{DC}|, becomes nearly maximum. Simultaneously, ion bombardment on the ground side of the plasma 106 (e.g., the showerhead 103), defined by |Vₚₗₐ|, becomes nearly minimum. Operating the process chamber accordingly enables maximizing etching on the substrate 137 while simultaneously minimizing particle generation from the showerhead 103. Adjusting |Vₚₗₐ−V_{DC}| to nearly a maximum value while adjusting |Vₚₗₐ| to nearly a minimum value, will be referred to hereinafter as RF tailored voltage.

The electrode 105 is connected to RF generators 108₁, 108₂, 108ₙ at frequencies of f₁, f₂, . . . fₙ, respectively, via the n-frequency RF match 102. In general, an RF voltage at the substrate support 104 is represented by Equation 1:

V(t)=Σᵢ₌₁ⁿVᵢ sin(ωᵢ+ϕᵢ) (1)

where Vᵢ and ϕᵢ are a voltage and a phase, respectively, at

$${f}_{i} = \frac{{ω}_{i}}{2 π}$$

and where ωᵢ is angular frequency. To keep commensurate RF periods, the frequency f₁ is the i-th harmonic frequency of a fundamental frequency f₁:

fᵢ=i·_{f} where i=1,2 . . . n (2)

Equation (2) facilitates implementation of a timing clock in hardware.

In the process chamber 101, the plasma 106 is generated with a time averaged bulk plasm potential of Vₚₗₐ. A time-averaged self-bias DC voltage of V_{DC} forms on the surface of a substrate 137 as a result of plasma generation within the process chamber 101.

For modeling illustration, Equation (1) is further assumed in the form of:

$$V ( t ) = {V}_{1} {\sum }_{i = 1}^{n} \frac{n - i + 1}{n} sin ( {ω}_{i} + {φ}_{i} ) \qquad ( 3 )$$

Furthermore, when Equation (3) is limited at n=2:

V(t)=V₁({sin(ω₁+ϕ₁)+½ sin(ω₂+ϕ₂)} (4)

In Equation 3, an amplitude of the harmonic is normalized by that of the fundamental harmonic. As the harmonic order increases, the amplitude decreases, e.g., the amplitude of the n-th harmonic is 1/n of the fundamental harmonic. It is believed to be advantageous to predominantly operate the fundamental harmonic for processing and other harmonics as adjusted terms to satisfy the RF tailored voltage condition where |Vₚₗₐ−V_{DC}| is near a maximum value and |Vₚₗₐ| is near a minimum value.

In the dual frequency system, for example when f₁=13.56 MHz and f₂=27.12 MHz, the phase difference between the two frequencies is defined by:

ϕ≡ϕ₂−ϕ₁ (5)

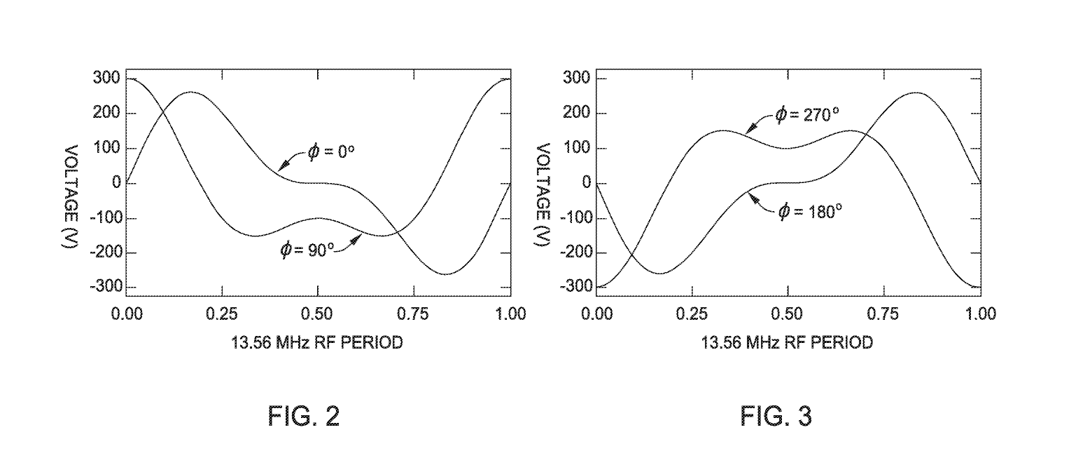

FIGS. 2 and 3 illustrate calculated RF voltage forms according to an example. When applying a self-consistent plasma modelling to the geometry of FIG. 1 with V₁=200 V and ϕ₁=0, the voltage wave form results are obtained for ϕ=0°, 90°, 180°, 270° as functions of normalized time in the FIGS. 2 and 3.

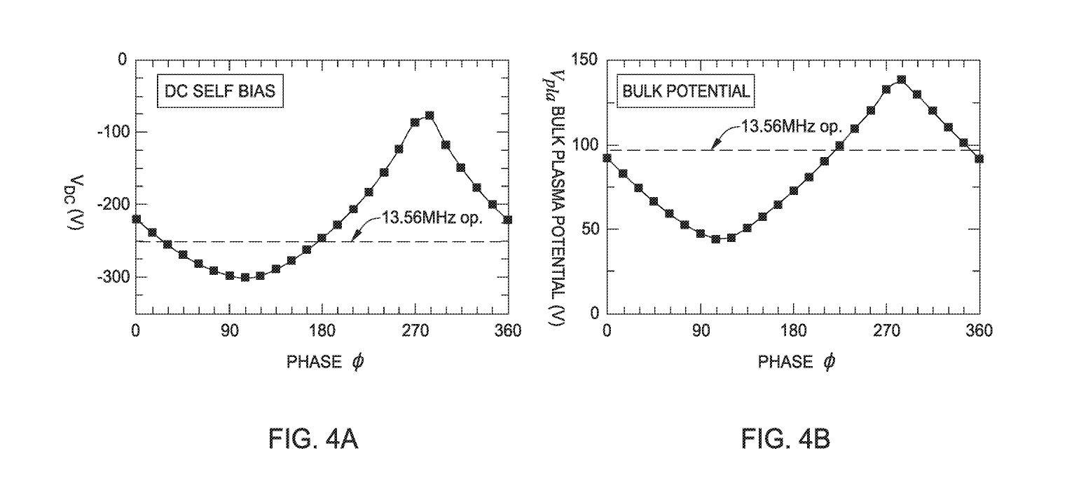

FIG. 4A illustrates a calculated DC self-bias voltage form according to the example. Calculated V_{DC} formed on the substrate support 104 illustrated in FIG. 1 is shown as a function of ϕ in FIG. 4A. Calculated Vₚₗₐ is shown as a function of ϕ in FIG. 4B. As illustrated in FIGS. 4A and 4B, the minimum of |Vₚₗₐ| is about 60 V and the maximum of |Vₚₗₐ−V_{DC}| is about 360 V at about ϕ=100°.

Since the ion bombardment voltages to the electrode 105 and the showerhead 103 are given by and |Vₚₗₐ−V_{DC}| and |Vₚₗₐ|, respectively, plasma processing at ϕ=100° provides near the minimum ion bombardment on the showerhead 103, thus reducing particle generation from the showerhead 103, and near the maximum bombardment to the substrate 137 on the substrate support 104, enhancing ion etching on the substrate 137. In other words, operating at ϕ=100° maximizes etching rates on the substrate 137 while simultaneously minimizing particle generation from the showerhead 103. Thus, particle generation from the showerhead 103 is minimized by varying the phase difference ϕ during a dual frequency plasma processing operation.

It is contemplated that plasma processing may occur with an n-frequency RF match 102 which uses more than two different frequencies, or with a second frequency which is an integer multiple of the first frequency, where the integer multiple is greater than 1. For example, a higher order harmonic, f₂, may be replaced with the third harmonic of f₁, which is 13.56 MHz, in Equation 4 (i.e., f₂=40.68 MHz).

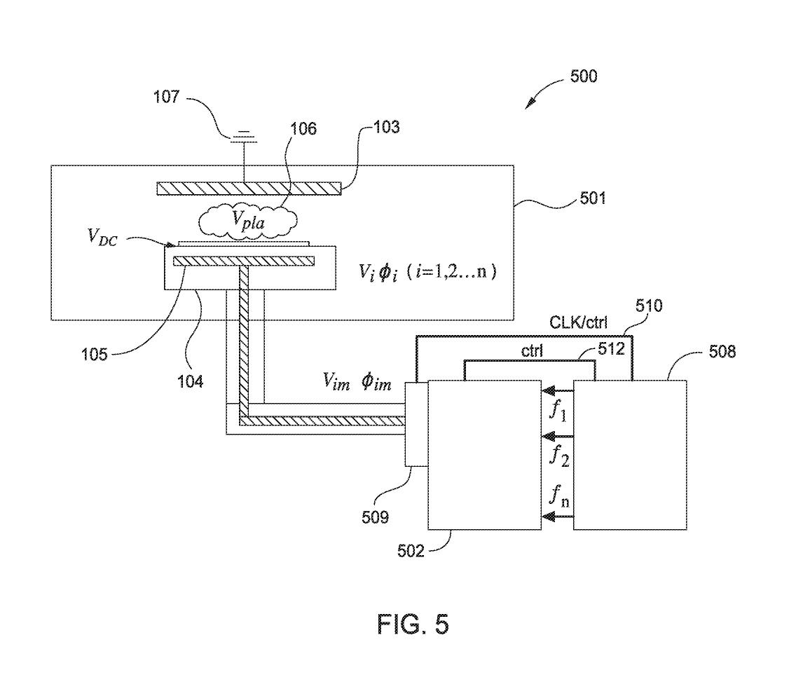

FIG. 5 depicts a schematic view of a processing system 500 according to an embodiment of the disclosure, which can be combined with one or more embodiments described above. The processing system 500 is similar to the processing system 100, but includes a single n-frequency generator 508, an n-frequency RF match 502 coupled to and downstream of the n-frequency RF generator 508, and a voltage monitor 509 coupled to and downstream of the n-frequency RF match 502. While a single RF generator 508 is shown, it is contemplated that multiple RF generators may be employed in the processing system 500.

To facilitate more accurate control and adjustment of processing parameters, the voltage monitor 509 detects voltage downstream of the n-frequency RF match 502, which corresponds to the voltage applied to the electrode 105 by a linear relation determined by a geometrical structure of the process chamber 501 (described hereinafter). Detecting voltage downstream of the n-frequency RF match 502 provides a more accurate indication of conditions in the process chamber 501, thus improving adjustments made to the processing parameters.

To facilitate process control, the n-frequency RF generator 508 receives a signal from the voltage monitor 509 via a connection 510. In response, the RF generator 508 generates RF power signals at each frequency to satisfy the RF tailored voltage condition operation at the electrodes 105 and 103. The n-frequency RF generator 508 may also receive a signal from the RF match 502 via a connection 512.

Determination of phase and amplitude adjustment, as described above, utilizes the parameters Vᵢ and ϕᵢ (i=1, 2, . . . n), which are defined at the substrate support 104. However, in the processing system 500, RF voltages and phases should be post-match (i.e., downstream of the RF match 502) as Vᵢₘ and ϕᵢₘ (i=1, 2, . . . n). Hence, the derived values Vᵢ and ϕᵢ in Equation (1) are transformed to post RF match 502 values defined as Vᵢₘ and ϕᵢₘ, calculated by a transform matrix:

$$[ \begin{matrix} \\ \end{matrix} ] = [ \begin{matrix}{A}_{i} & {B}_{i} \\ {C}_{i} & {D}_{i}\end{matrix} ] [ \begin{matrix}{\tilde{V}}_{l} \\ \end{matrix} ] \qquad ( 6 )$$

where all values are defined as complex numbers. Hence, the values in Equation (1) are converted to the form of:

\tilde{V}ᵢ=−j·Vᵢe^{jϕ}^{ᵢ} (7)

[symbol] is defined at the substrate support 104 and is calculated, for one example, based on the modeling illustrated in FIGS. 2, 3, 4A, and 4B. The ABCD matrix can be calculated from the geometry of the process chamber 501, and more specifically, a series of transmission lines and some combination of capacitors and inductors. It is noted that ϕ₁ has arbitrariness. Thus, ϕ₁ can be defined as ϕ₁=0 without losing generality. During operation, the RF voltage parameters Vᵢ and (P post RF match 502 are measured by the n-frequency RF voltage monitor 509, denoting the measured values as Vᵢₘₑ and ϕᵢₘₑ. Experimental determination of the RF voltage parameters enables determination of an RF tailored voltage.

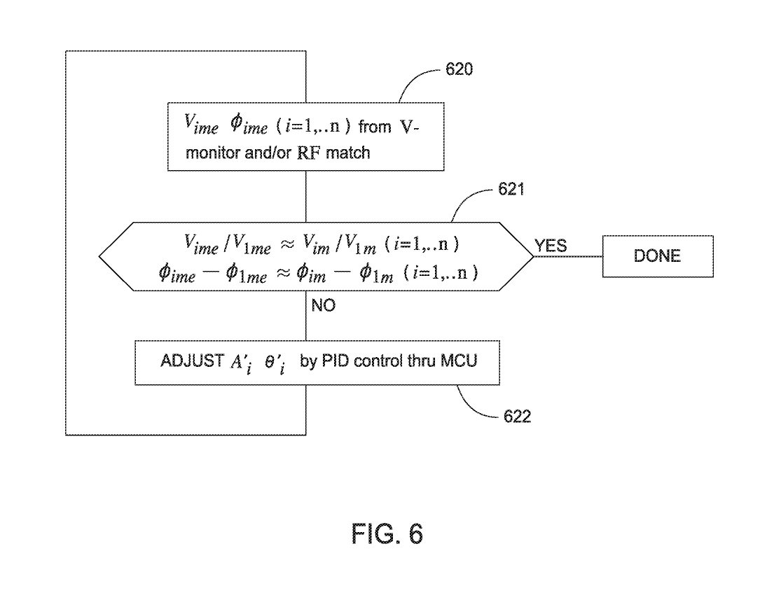

FIG. 6 depicts a flow chart of an algorithm to identify an RF tailored voltage by attaining target RF voltage parameters Vᵢₘ and ϕᵢₘ. In some embodiments, Vᵢₘ and ϕᵢₘ are user defined target parameters. In other embodiments, Vᵢₘ and ϕᵢₘ are measured parameters of a second RF signal. During operation 620, experimental parameters Vᵢₘₑ and ϕᵢₘₑ are measured by the n-frequency RF voltage monitor 509. During operation 621, it is determined whether the measured experimental parameters Vᵢₘₑ and ϕᵢₘₑ satisfy the conditions of Equations (8) and (9):

Vᵢₘₑ/V₁ₘₑ≈Vᵢₘ/V₁ₘ (8)

ϕᵢₘₑ−ϕ₁ₘₑ≈ϕᵢₘ−ϕ₁ₘ (9)

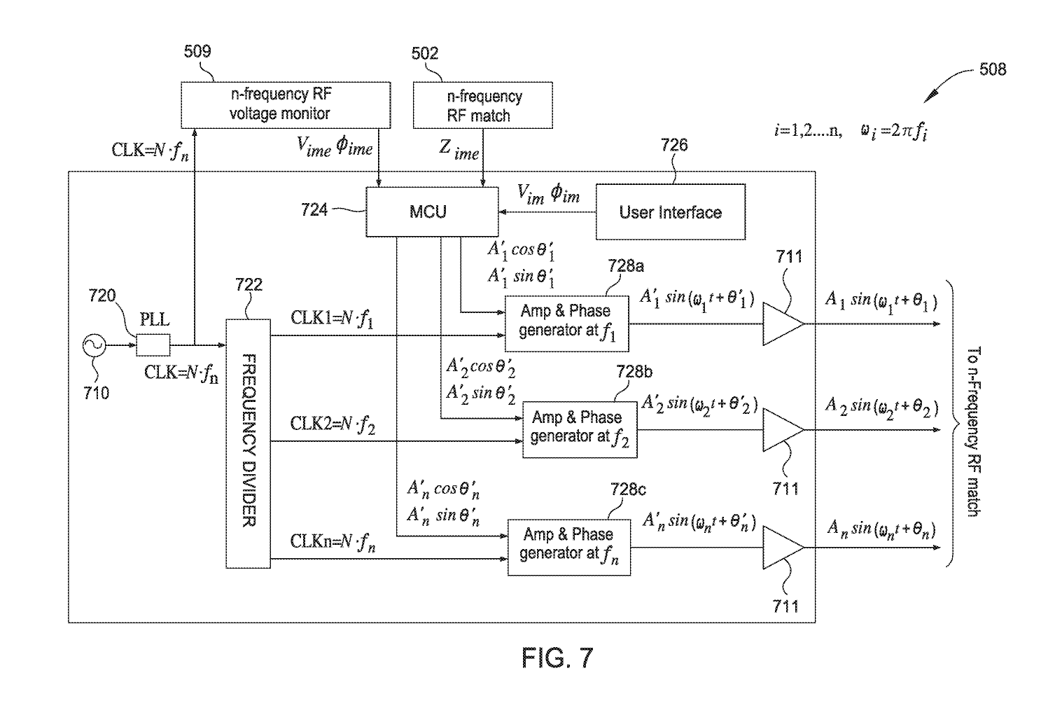

If the measured parameters Vᵢₘₑ and ϕᵢₘₑ satisfy Equations (8) and (9) within a user-defined tolerance, no adjustments are performed on the n-frequency RF generator 508. The user-defined tolerance is empirical, typically. The user-defined tolerance of the amplitude ratio (Equation 8) is about 5 percent, for example, between about 3 percent and about 7 percent, such as between about 4 percent and about 6 percent. The user-defined tolerance for the relative angle (Equation 9) is between about 3 degrees and about 8 degrees, for example, between about 4 degrees and about 6 degrees. However, if the algorithm of operation 621 is not satisfied by the measured values of Vᵢₘₑ and ϕᵢₘₑ, an amplitude A′ᵢ and a phase θ′ᵢ of a seed RF voltage (see FIG. 7) is generated inside the n-frequency RF generator 508 through a negative feedback control, e.g., a proportional integral derivative (PID) controller, performed inside of a micro control unit (MCU), as illustrated in operation 622. Stated otherwise, the PID and MCU facilitate adjustment of the n-frequency RF generator 508, in response to the measured values Vᵢₘₑ and ϕᵢₘₑ, to effect a desired voltage and phase downstream of the RF match 502. The feedback control is performed for each frequency, fᵢ, where i=2, 3, . . . n while A′₁ and θ′₁ are constant.

In one example, operation 620 is subsequently followed by operation 621. If operation 621 is satisfied, processing of the substrate proceeds without adjustment to voltage and phase. If operation 621 is not satisfied, operation 622 is performed and operations 620-622 are repeated until operation 621 is satisfied.

In some examples, the n-frequency RF voltage monitor 509 may be not sufficiently precise at frequencies over 40 MHz because both RF voltage and current downstream of the RF match 502 are relatively high, and the phase angle between these two is close to 90 degrees. At around a 90 degree phase angle, a small difference, for example, 1 degree, results in a large difference in power and can lead to erroneous readings of the RF voltage and/or current. In such a case, the complex-valued impedance Zᵢₘₑ (shown in FIG. 7) is determined by

$${Z}_{ime} = \frac{1}{{Y}_{ime}} ,$$

where Yᵢₘₑ is the admittance at a frequency fᵢ, which is derived from the RF matching condition inside the n-frequency RF match 502 and can be used to calculate Vᵢₘₑ in Equation (10):

$${V}_{ime} = \sqrt{\frac{2 {p}_{ime}}{Re ( {Y}_{ime} )}} \qquad ( 10 )$$

where ϕᵢₘₑ is a power delivered to the process chamber, such as the process chamber 501 depicted in FIG. 5, at the frequency, fᵢ. The measurement of Zᵢₘₑ is calibrated by a vector network analyzer (not shown) disposed in the RF match 502. Thus, Equation (10) is highly accurate.

It is noted that the n-frequency RF voltage monitor 509 is used to measure phase angles, ϕᵢₘₑ, which include systematic errors when measuring the absolute value of the phase angles. However, the systematic error is cancelled by the subtraction in Equation (9). Additionally, the statistical error of the derived values is reduced by using time-average variables, thus improving accuracy of the derived results. Consequently, the effect of error in Equation (9) can be alleviated.

FIG. 7 is a block diagram of the n-frequency RF generator 508 illustrated in FIG. 5. The n-frequency RF generator 508 includes a phase-locked loop (PLL) circuit 720, a frequency divider 722, an MCU 724, a user interface 726, one or more generators 728a-728c (three are shown), and one or more power amplifiers 711 (three are shown) each connected to a respective generator 728a-728c. The PLL circuit 720 receives a signal from a crystal oscillator or an external clock generator 710 to generate a clock signal of CLK=N·fₙ, where N is an arbitrary integer, e.g., 2²-2⁶. The CLK signal is transmitted to the frequency divider 722 to generate a set of CLK signals CLK i (where i=1, . . . n), each of which is transmitted to a respective generator 728a-728c configured to generate an amplitude and phase at a frequency of fᵢ.

The CLK signal is also transmitted to an n-frequency RF-voltage monitor (such as n-frequency RF voltage monitor 509) that measures Vᵢₘₑ and ϕᵢₘₑ at fᵢ. As shown in Equation (10), Vᵢₘₑ can be replaced with the measurement of the voltage at the n-frequency RF match 502. The values of Vᵢₘₑ and ϕᵢₘₑ are provided to the MCU 724, which calculates an amplitude A′ᵢ and a phase θ′ᵢ for a seed RF voltage through a PID controller as shown in FIG. 6 from the measured values Vᵢₘₑ, ϕᵢₘₑ and the target values Vᵢₘ, ϕᵢₘ input by a user at the user interface 726. The amplitude A′ᵢ and the phase θ′ᵢ represent the adjustment to the measured values of Vᵢₘₑ and ϕᵢₘₑ. Once the measured values of Vᵢₘₑ and ϕᵢₘₑ match the target values of Vᵢₘ and ϕᵢₘ, respectively, the RF signal is applied to the electrode 105 illustrated in FIGS. 1 and 5.

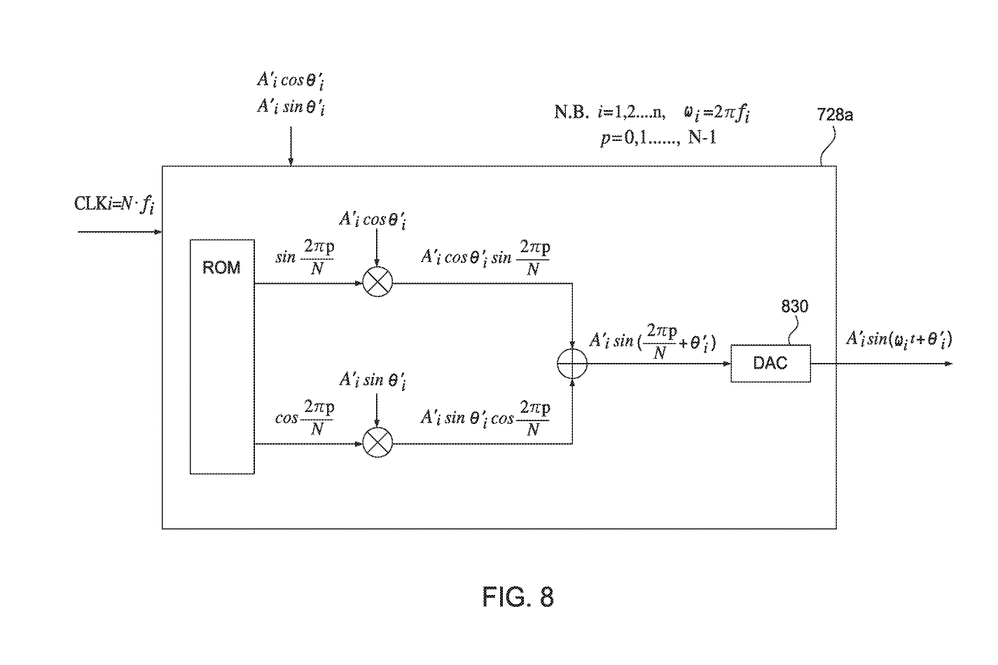

FIG. 8 depicts a block diagram of an amplitude and phase generator 728a, according to an embodiment of the disclosure, which can be combined with one or more embodiments described above. It is to be understood that generators 728b and 728c are similarly configured. Using information of A′ᵢ cos θ′ᵢ and A′ᵢ sin θ′ᵢ received from the MCU 724 shown in FIG. 7, an In-and-Quadrature phase (IQ) modulation operation at CLKi=N·fᵢ, synthesizes a digital seed signal of

$${A}_{i}^{′} sin ( \frac{2 π p}{N} + {θ}_{i}^{′} ) ,$$

where p=0, 1, . . . N−1, eventually converting the digital seed signal to an analog seed of A′ᵢ sin(ωᵢt+θ′ᵢ) in the digital to analog converter (DAC) 830. As shown in FIG. 7, the signal from the RF generator A′ᵢ sin(ωᵢt+θ′ᵢ) is amplified by a power amplifier 711 to Aisin(ωᵢt+θᵢ). The amplified signal of Aisin(ωᵢt+θᵢ) is transmitted to the n-frequency RF match 502 which converts the amplified signal to Vᵢₘₑ sin(ωᵢt+A′ᵢₘₑ) at the output of the RF match.

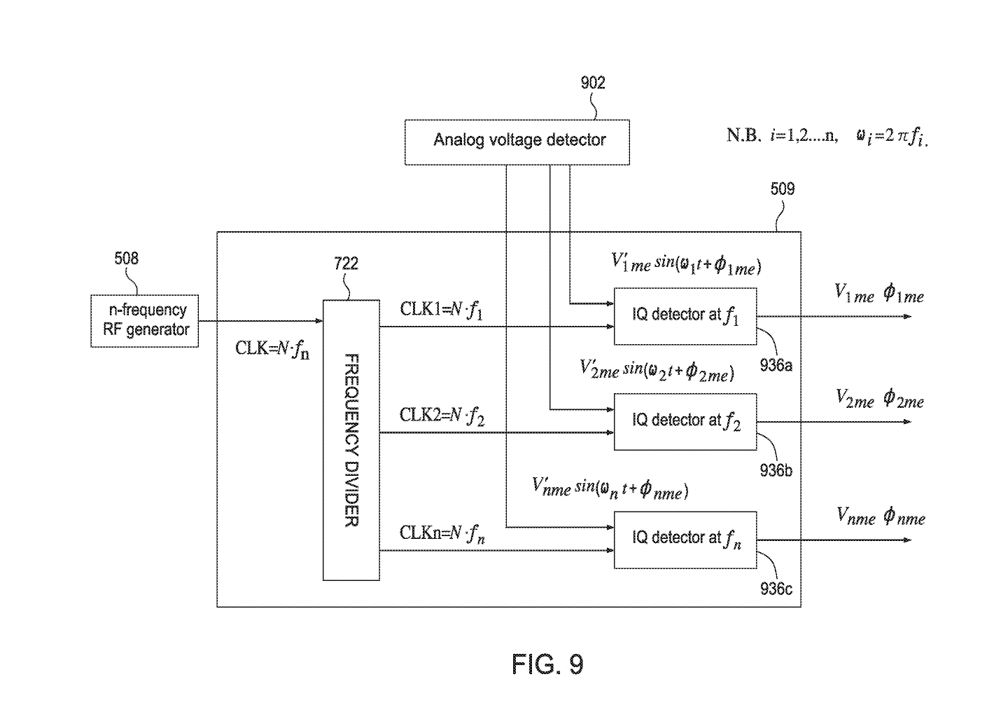

FIG. 9 is a diagram of the n-frequency RF voltage monitor 509 receiving the basic clock signal of CLK=N. fₙ from the n-frequency RF generator 508. An analog voltage detector 902, e.g., a capacitive voltage divider, measures n-set of RF voltages in the form of V′ᵢₘₑ sin(ωᵢt+ϕᵢₘₑ) at a frequency of fᵢ (i=1, . . . n), where V′ᵢₘₑ and Vᵢₘₑ are related by a scale factor. The frequency divider 722 generates n-set of CLK i (i=1, . . . n) to operate respective IQ detectors 936a-936c (three are shown) at a frequency of fᵢ. The IQ detectors 936a-936c derive Vᵢₘₑ and ϕᵢₘₑ from the input RF voltage V′ᵢₘₑ sin(ωᵢt+ϕᵢₘₑ).

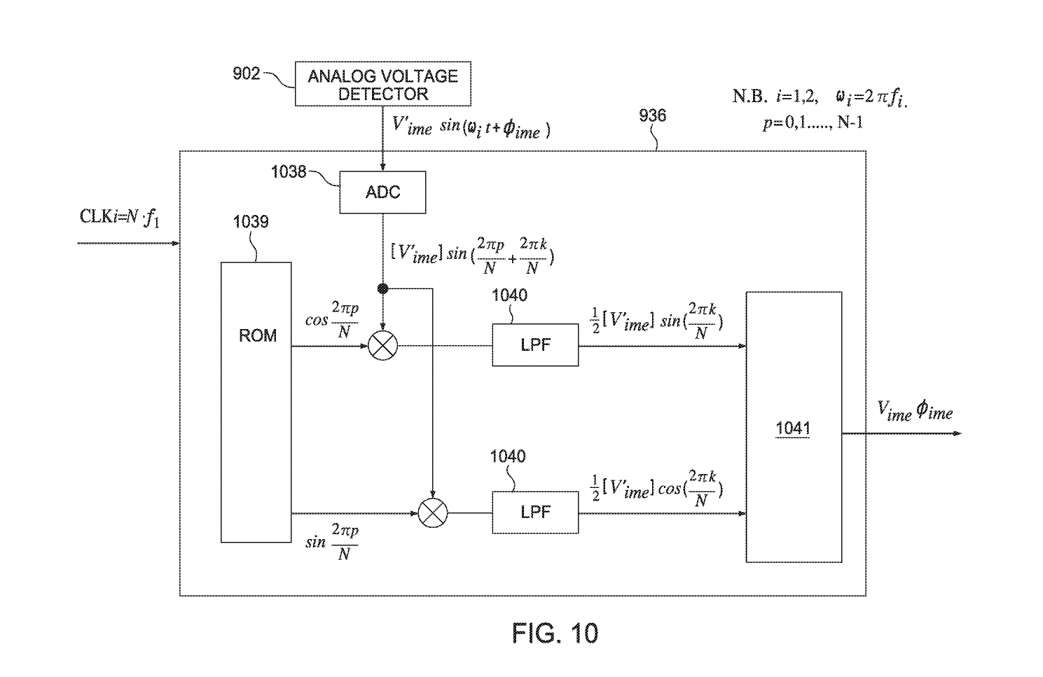

FIG. 10 illustrates a block diagram of an IQ detector 936 at a frequency of fᵢ (i=1, . . . n). The analog to digital converter (ADC) 1038 converts the analog input of V′ᵢₘₑ sin(ωᵢt+ϕᵢₘₑ) from the analog voltage detector 902 to the digital value of

$$[ {V}_{ime}^{′} ] sin ( \frac{2 π p}{N} + \frac{2 π k}{N} ) .$$

The digital value is multiplied by

$$cos \frac{2 π p}{N} and sin \frac{2 π p}{N}$$

from the ROM 1039. The converted signal is transmitted to low pass filters (LPF) 1040. The low pass filters produce the output of

$$\frac{1}{2} [ {V}_{ime}^{′} ] sin ( \frac{2 π k}{N} ) and \frac{1}{2} [ {V}_{ime}^{′} ] cos ( \frac{2 π k}{N} ) .$$

The output of the low Pass filters is transmitted to a digital signal processor (DSP) 1041. The DSP 1041 may include a coordinate rotation digital computer (CORDIC). A CORDIC algorithm and other digital signal processing are utilized to derive Vᵢₘₑ and ϕᵢₘₑ.

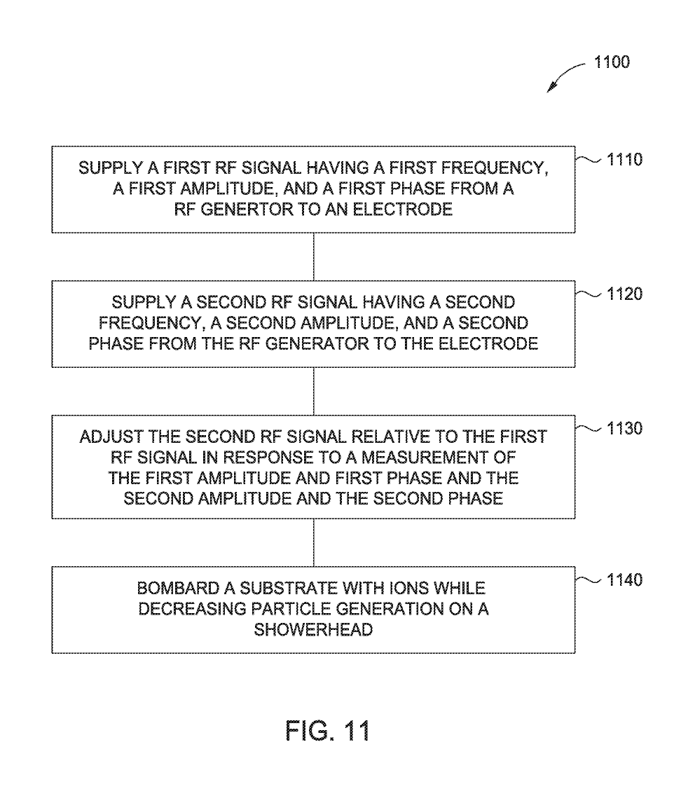

FIG. 11 depicts a method 1100 of controlling ion bombardment in a process chamber according to an embodiment of the disclosure, which can be combined with one or more embodiments described above. During operation 1110, a first RF signal having a first frequency, a first amplitude, and a first phase is transmitted from an RF generator to an electrode embedded in a substrate support in a process chamber.

During operation 1120, a second RF signal having a second frequency, a second amplitude, and a second phase is transmitted from the RF generator to the electrode. In one embodiment, which can be combined with one or more embodiments described above, the second RF signal has a harmonic frequency of the frequency of the first RF signal. During operation 1130, the second RF signal is adjusted relative to the first RF signal in response to a measurement of the first amplitude, the first phase, the second amplitude, and second phase. In one embodiment, which can be combined with one or more embodiments described above, an amplitude and a phase for a seed RF voltage as discussed above is determined based on the measurements of the first RF signal and the second RF signal. The amplitude and the phase of the seed RF voltage may be used to adjust the second RF signal. At operation 1140, ion bombardment on a substrate is increased and particle generation on a showerhead disposed in the chamber is decreased as a result of the RF modulation.

Utilization of the method 1100 for plasma processing reduces particles generated from the showerhead by identifying the phases ϕᵢₘ (i=2, . . . n) at which the |Vₚₗₐ| becomes nearly minimum, as shown above. At ϕᵢₘ (i=2, . . . n), it is also identified that |Vₚₗₐ−V_{DC}| becomes nearly maximum, thus maximizing deposition or etching on the substrate while simultaneously reducing particle generation from the showerhead. The |Vₚₗₐ−V_{DC}| corresponds to ionized particle impact on the substrate during etching or deposition, and the |Vₚₗₐ| corresponds to ionized particle impact on the showerhead. Therefore, by identifying the phases where the voltage on the substrate support is maximized and the voltage on the showerhead is minimized, ionized particle impact at the showerhead is minimized (reducing particle flaking from the showerhead) while deposition and/or etching is increased and/or maximized at or adjacent to the substrate.

While the foregoing is directed to embodiments of the present disclosure, other and further embodiments of the disclosure may be devised without departing from the basic scope thereof, and the scope thereof is determined by the claims that follow.

What is claimed is:

1. A substrate processing method, comprising:
supplying a first RF signal having a first frequency, a first amplitude, and a first phase from an RF generator to an electrode embedded in a substrate support disposed in a process chamber;
supplying a second RF signal having a second frequency, a second amplitude, and a second phase from the RF generator to the electrode; and
adjusting the second RF signal relative to the first RF signal to generate ions, the adjusting performed in response to a measurement of the first amplitude, the first phase, the second amplitude, and the second phase.

2. The method of claim 1, further comprising:
generating a time averaged self-bias DC voltage on a surface of a substrate disposed on the substrate support.

3. The method of claim 1, wherein the first frequency and the second frequency are harmonic.

4. The method of claim 3, wherein the first frequency and the second frequency are adjacent harmonic frequencies.

5. The method of claim 1, further comprising:
supplying more than two RF signals from the RF generator to the electrode.

6. The method of claim 5, wherein the more than two RF signals comprise harmonic frequencies.

7. The method of claim 2, wherein particle generation on a showerhead is minimized during etching of the substrate.

8. The method of claim 7, wherein a surface area of a surface of the substrate support is smaller than a surface area of the showerhead.

9. The method of claim 2, wherein a number of ions for etching are maximized adjacent to the substrate.

10. A system for processing a substrate, comprising:
a process chamber defining a process volume therein;
a substrate support disposed in the process volume;
a showerhead disposed opposite the substrate support in the process volume;
an electrode embedded in a substrate support of the substrate support;
an RF generator coupled to the electrode to supply a first RF signal having a first frequency, a first amplitude, and a first phase and a second RF signal having a second frequency, a second amplitude, and a second phase to the electrode; and
a controller connected to the RF generator to adjust the second RF signal relative to the first RF signal in response to a measurement of the first amplitude, the first phase, the second amplitude, and the second phase to generate ions for etching a substrate.

11. The system of claim 10, further comprising:
generating a time averaged self-bias DC voltage on a surface of a substrate disposed on the substrate support.

12. The system of claim 10, wherein the first frequency and the second frequency are harmonic.

13. The system of claim 12, wherein the first frequency and the second frequency are adjacent harmonic frequencies.

14. The system of claim 10, wherein the RF generator supplies more than two RF signals to the electrode.

15. The system of claim 14, wherein the more than two RF signals comprise harmonic frequencies.

16. The system of claim 10, wherein particle generation on the showerhead is minimized as a result of an adjustment to the second RF signal.

17. The system of claim 10, wherein a number of ions for etching are maximized adjacent to a substrate disposed on the substrate support.

18. The system of claim 10, wherein a surface area of the substrate support is smaller than a surface area of the showerhead.

19. An apparatus for processing a substrate, comprising:
a process chamber having a substrate support disposed in a process volume of the process chamber;
a showerhead disposed opposite the substrate support in the process volume of the process chamber;
an electrode embedded in a substrate support of the substrate support;
an RF generator coupled to the electrode to supply a first RF signal having a first frequency, first amplitude, and a first phase and a second RF signal having a second frequency, a second amplitude, and a second phase to the electrode; and
a controller connected to the RF generator to adjust the second RF signal relative to the first RF signal in response to a measurement of the first amplitude, the first phase, the second amplitude, and the second phase to generate ions, a number of ions maximized adjacent to the substrate support and minimized adjacent to the showerhead.

20. The apparatus of claim 19, wherein the first frequency and the second frequency are harmonic.
